(19) United States
(12) Patent Application Publication
(10) Pub. No.: US 2021/0035959 A1
(43) Pub. Date: Feb. 4, 2021

(54) DISPLAY PANEL AND DISPLAY DEVICE

(71) Applicant: WUHAN CHINA STAR OPTOELECTRONICS TECHNOLOGY CO., LTD, Wuhan, Hubei (CN)

(72) Inventor: Yong YANG, Wuhan, Hubei (CN)

(21) Appl. No.: 16/631,177

(22) PCT Filed: Sep. 23, 2019
(86) PCT No.: PCT/CN2019/107180

§ 371 Date: Jan. 15, 2020

(30) Foreign Application Priority Data
Jul. 29, 2019 (CN) 201910688636.2

(51) Int. Cl. H01L 25/075; H01L 33/58; H01L 33/50

(52) U.S. Cl. CPC H01L 25/0753; H01L 33/507; H01L 33/58

(57) ABSTRACT

The present invention provides a display panel and a display device. Multiple florescence film units are placed on a diffusion plate and arranged spaced apart in an array corresponding to light-emitting-diode (LED) chips. Accordingly, a portion of blue light emitted by the LED chips does not pass through the florescence film units and compensates for a yellowish color of partial light. Therefore, a “yellow edge” problem at boundaries of different areas is improved, color distortion is avoided, and high color reproduction and high contrast displays are achieved. Moreover, a thickness of the fluorescent film unit is thinner than that of a conventional fluorescent film, which is conducive to thinning of the display panel.

### 1. FIELD OF DISCLOSURE

The present invention relates to display devices and in particular, to a display panel and a display device.

### 2. DESCRIPTION OF RELATED ART

Display devices can convert data of a computer into various characters, numbers, symbols, or images, and can input commands or data into a computer by means of an input tool like a keyboard to add, modify, or change a display content at any time using hardware and software of a system. The display devices are categorized into plasma displays, liquid crystal displays, light-emitting-diode displays, and cathode-ray tube (CRT) displays.

Mini LED, also known as “sub-millimeter light-emitting diode”, has many advantages such as being ultra-thin, special-shaped displays, local dimming (backlight adjustment technology), high contrast ratios, narrow border, and high-dynamic range (HDR). Therefore, mini LED has been favored by people. In the field of display products for consumers, mini LED has a major advantage of local dimming which can achieve high-contrast displays. It can realize extremely bright and extremely dark gray-scale changes in a display area by means of backlight control in different areas to improve display quality.

Conventional mini LEDs mostly adopt a chip-on-board (COB) encapsulation technology. Therefore, when LED chips illuminate light, boundaries of different areas have color shifts due to different optical paths and optical waveguides in a film material. The difference in color causes a color shift of a displayed image. There is a solution to overcome this shortcoming by adjusting a channel brightness algorithm. However, although this technical solution is mature enough, such algorithms need to be adjusted according to different pictures, which will increase product costs and power consumption. Therefore, this solution is not suitable for mass production, and it is necessary to find a new type of display panel to solve the above problems.

### SUMMARY

It is an objective of the present invention to provide a display panel and a display device, which can solve color unevenness caused by local dimming technology of mini LEDs, thereby improving image quality, improving contrast, and avoiding color distortion.

Accordingly, the present invention provides a display panel. The display panel comprises: a back light, a light-emitting lamp plate, a diffusion plate, and a plurality of florescence film units. The light-emitting lamp plate is disposed on the back plate, and the light-emitting lamp plate comprises a lamp base plate and a plurality of light-emitting-diode (LED) chips, wherein the LED chips are disposed spaced apart from each other and arranged as an array on the lamp base plate. The diffusion plate is disposed on the light-emitting lamp plate. The florescence film units are disposed on one side of the diffusion plate facing the light-emitting lamp plate and arranged spaced apart in an array corresponding to the LED chips.

A thickness of each of the florescence film units is 0.05 mm to 0.08 mm.

The florescence film units are disposed on the diffusion plate by spraying or brushing.

A length of each of the fluorescent film units is one to three times a length of each of the LED chips.

A width of each of the fluorescent film units is one to three times a width of each of the LED chips.

Material of the fluorescent film units comprises one or more of silicate and yttrium aluminum garnet.

A distance between each two adjacent ones of the LED chips is 0.7 mm to 10 mm.

A distance between each two adjacent ones of the fluorescent film units is 0.1 mm to 3 mm.

The display panel further comprises a prism sheet, wherein the prism sheet is disposed on one side of the diffusion plate away from the back plate.

The present invention provides a display device. The display device comprises the display panel.

### Advantages of the Present Invention

The present invention provides a display panel and a display device. According to the present invention, the fluorescent film units are disposed spaced apart from each other in an array on the diffusion plate and arranged corresponding to the LED chips. Moreover, by means of arranging the fluorescent film units spaced apart in an array, partial blue light of the LED chips does not pass through the fluorescent film units and can compensate for yellowish color of partial light, so a “yellow edge” problem at boundaries of different areas is improved, thereby avoiding color distortion and achieving high color reproduction and high contrast displays. In addition, the thickness of the fluorescent film unit is thinner than that of a conventional fluorescent film, which is conducive to thinning of the display panel.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work.

FIG. 1 is a schematic structural view illustrating a display panel of the present invention;

FIG. 2 is a schematic view illustrating light emission in a prior art;

FIG. 3 is a schematic view illustrating light emission in the present invention;

FIG. 4 is a schematic view illustrating florescence film units and light-emitting-diode (LED) chips of the present invention;

FIG. 5 is a first schematic view illustrating manufacturing of the florescence film units;

FIG. 6 is a second schematic view illustrating manufacturing of the florescence film units;

FIG. 7 is a third schematic view illustrating manufacturing of the florescence film units; and

FIG. 8 is a fourth schematic view illustrating manufacturing of the florescence film units.

### DETAILED DESCRIPTION OF EMBODIMENTS

Embodiments of the present invention are described in detail below with reference to the accompanying drawings. Accordingly, a technical content of the present invention is made clear, so that those skilled in the art will more readily understand how to implement the invention. The present invention may, however, be embodied in many different forms, and a protection scope of the present invention is not limited to the embodiments described herein.

The directional terms in the present disclosure, such as “upper”, “lower”, “front”, “rear”, “left”, “right”, “inside”, “outside”, and “lateral”, are merely illustrative with reference to the accompanying drawings, and are not intended to limit the protection scope of the present invention.

In the drawings, structurally identical components are denoted by the same reference numerals, and structural or functionally similar components are denoted by like reference numerals. Moreover, the size and thickness of each component shown in the drawings are for illustrative purposes to ease understanding, and the present invention does not limit the size and thickness of each component.

When a component is described as “on” another component, the component can be placed directly on the another component; or alternatively, there can also be an intermediate component, and the intermediate component is placed on the another component. When a component is described as “mounted to” or “connected to” another component, it can be understood as “directly mounted to” or “directly connected to”; or alternatively, the component is “mounted to” or “connected to” the another component through an intermediate component.

### First Embodiment

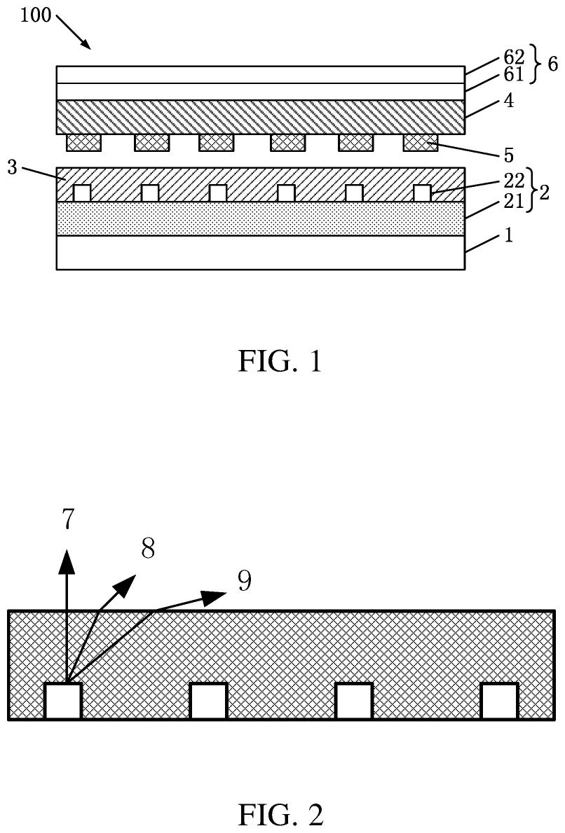

FIG. 1 shows a display panel 100. The display panel comprises: a back plate 1, a light-emitting lamp plate 2, a protective layer 3, a diffusion plate 4, a plurality of florescence film units 5, and a prism sheet 6.

The back plate 1 has a rubber iron frame structure, and mainly functions to protect and support an upper structure.

The light-emitting lamp plate 2 comprises a lamp base plate 21 and a plurality of light-emitting-diode (LED) chips 22, wherein the LED chips 22 are disposed spaced away from each other and arranged as an array on the lamp base plate 21. In detail, the LED chips 22 can be electrically connected to a copper wire on the lamp base plate 21 by means of soldering to emit light. In addition, the protective layer 3 can also be formed by applying a transparent adhesive layer on the light-emitting lamp plate 2, so that the LED chips 22 can be prevented from being intruded by water and oxygen.

The diffusion plate 4 is disposed on the protective layer 3. The diffusion plate 4 may has a diffuser or a film structure having a diffusion agent on its surface, and the diffusion agent is applied to one side of the diffusion plate 4 away from the back plate 1.

The florescence film units 5 are disposed on one side of the diffusion plate 4 facing the light-emitting lamp plate 2 and arranged spaced apart in an array corresponding to the LED chips 22.

The prism sheet 6 is disposed on one side of the diffusion plate 4 away from the back plate 1. The prism sheet 6 comprises a lower prism sheet portion 61 disposed on one side of the diffusion plate 4 away from the back plate 1, and an upper prism sheet portion 62 disposed on the lower prism sheet portion 61. The upper prism sheet portion 62 and the lower prism sheet portion 61 are mainly used to increase brightness of the display panel 100.

By arranging the fluorescent film units 5 spaced apart from each other in an array, a portion of blue light emitted from the LED chips 22 does not pass through the fluorescent film units 5 and can compensate for undesirable yellowish color of partial light, thereby improving a “yellow edge” problem at boundaries of different areas, avoiding color distortion, and achieving high color reproduction and high contrast displays. On the other hand, since a thickness of the fluorescent film unit 5 is thinner than that of a conventional fluorescent film, it is more conducive to thinning of the display panel 100.

FIG. 2 shows a conventional mini LED structure manufactured by a chip-on-board (COB) technique, wherein a ratio of red to green to blue colors (RGB three primary colors) of light emitted by LED chips 32 through a fluorescent film layer changes according to a waveguide distance of the light. To be specific, the shorter the waveguide distance is, the less red and green light are excited, and the more bluish the outgoing light is; on the contrary, the outgoing light is yellowish, which is so-called a “yellow edge” phenomenon. Therefore, as shown in FIG. 2, after passing through the fluorescent film layer, a first ray 7, a second ray 8, and a third ray 9 exhibit colors from bluish to yellowish.

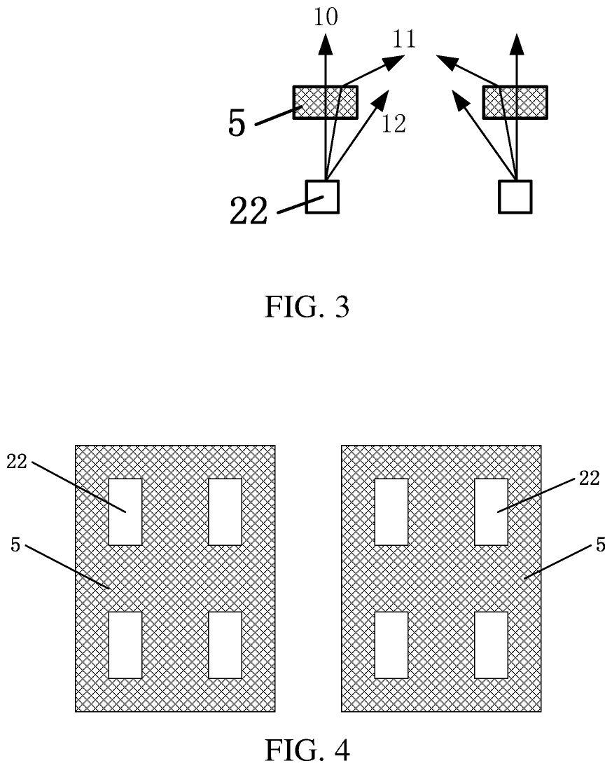

As shown in FIG. 3, a thickness of the fluorescent film unit 5 of the present invention is thinner than that of the conventional fluorescent film layer, which is conducive to thinning of the display panel 100. A fourth ray 10 and a fifth ray 11 emitted by the LED chips 22 are different in their waveguide distances in the fluorescent film unit 5, so an outgoing light of the fifth ray 11 is yellowish than an outgoing light of the fourth ray 10. Since the fluorescent film units 5 are disposed on the diffusion plate 4 and arranged in an array corresponding to the LED chips 22, there is a sixth ray 12 which does not pass through the fluorescent film unit 5, as shown in FIG. 3. The sixth ray 12 can compensate for a color shift problem between the outgoing lights of the fifth ray 11 and the fourth ray 10, improve the “yellow edge” problem at boundaries of different areas, thereby avoiding color distortion, and achieving high color reproduction and high contrast displays.

The thickness of each of the florescence film units 5 is 0.05 mm to 0.08 mm. The florescence film units 5 are disposed on the diffusion plate 4 by spraying or brushing.

As shown in FIG. 1 and FIG. 4, the LED chip 22 has light-emitting angles within a certain range. Accordingly, a size of the fluorescent film unit 5 is larger than a size of the LED chip 22, so that after passing through the fluorescent film unit 5, the blue light emitted by the LED chip 22 can be converted into RGB colors (three primary colors) to generate a white outgoing light. To be specific, a length of each of the fluorescent film units 5 is one to three times a length of each of the LED chips 22. A width of each of the fluorescent film units 5 is one to three times a width of each of the LED chips 22.

A distance between each two adjacent ones of the LED chips is 0.7 mm to 10 mm. A distance between each two adjacent ones of the fluorescent film units is 0.1 mm to 3 mm.

Material of the fluorescent film unit 5 comprises one or more materials of silicate and yttrium aluminum garnet. The fluorescent film unit 5 thus can well convert the blue light emitted from the LED chips 22 into RGB colors (three colors) to achieve white light emission.

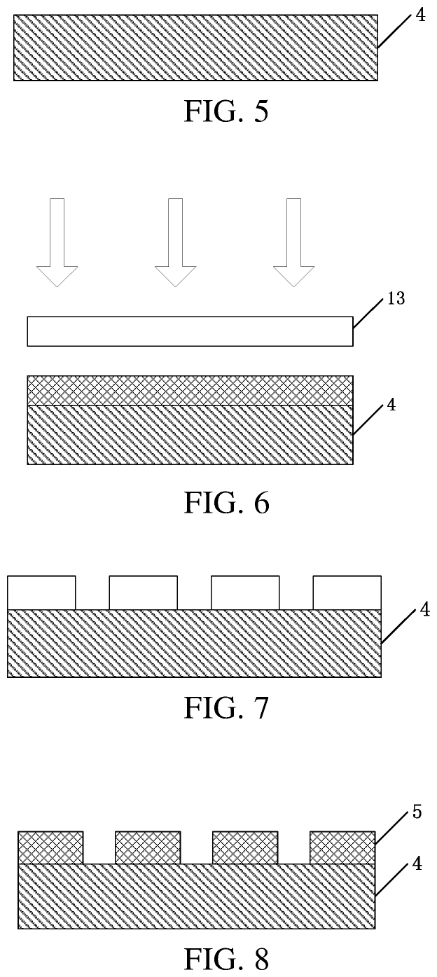

As shown in FIG. 5, FIG. 6, FIG. 7, and FIG. 8, the present invention also provides schematic views illustrating manufacturing of the fluorescent film units 5.

First, a diffusion plate 4 is provided, then a fluorescent film layer is formed on the diffusion plate 4 by a brushing process or a spraying process, and a patterned steel mesh 13 is placed on the fluorescent film layer, wherein a pattern of the steel mesh 13 is configured corresponding to the LED chips 22. After that, exposing, baking and curing processes are performed to form fluorescent film units 5 arranged spaced apart in an array corresponding to the LED chips 22.

The present invention further provides a display device according to another embodiment of the present invention. The display device comprises the display panel 100 of the present invention.

The display panel and the display device provided by the present invention have been described in detail above. It should be understood that the example embodiments described herein are to be considered as illustrative only, and are not intended to limit the present invention. Descriptions of features or aspects in each example embodiment should generally be considered as suitable features or aspects in other example embodiments. Although the present invention has been described with reference to the preferable embodiments, various modifications and changes can be made by those skilled in the art. The present invention is intended to cover such modifications and changes made within the protection scope of the appended claims. Any modifications, equivalents, or changes within the spirit of the present invention are deemed to be within the protection scope of the present invention.

What is claimed is:

1. A display panel, comprising:
a back plate;
a light-emitting lamp plate disposed on the back plate, the light-emitting lamp plate comprising a lamp base plate and a plurality of light-emitting-diode (LED) chips, wherein the LED chips are disposed spaced away from each other and arranged as an array on the lamp base plate;
a diffusion plate disposed on the light-emitting lamp plate; and
a plurality of florescence film units disposed on one side of the diffusion plate facing the light-emitting lamp plate and arranged spaced apart in an array corresponding to the LED chips.

2. The display panel according to claim 1, wherein a thickness of each of the florescence film units is 0.05 mm to 0.08 mm.

3. The display panel according to claim 1, wherein the florescence film units are disposed on the diffusion plate by spraying or brushing.

4. The display panel according to claim 1, wherein a length of each of the fluorescent film units is one to three times a length of each of the LED chips.

5. The display panel according to claim 1, wherein a width of each of the fluorescent film units is one to three times a width of each of the LED chips.

6. The display panel according to claim 1, wherein material of the fluorescent film units comprises one or more of silicate and yttrium aluminum garnet.

7. The display panel according to claim 1, wherein a distance between each two adjacent ones of the LED chips is 0.7 mm to 10 mm.

8. The display panel according to claim 1, wherein a distance between each two adjacent ones of the fluorescent film units is 0.1 mm to 3 mm.

9. The display panel according to claim 1, further comprising a prism sheet, wherein the prism sheet is disposed on one side of the diffusion plate away from the back plate.

10. A display device, comprising the display panel of claim 1.
